(19) United States
(12) Patent Application Publication
(10) Pub. No.: US 2026/0110978 A1
(43) Pub. Date: Apr. 23, 2026

(54) EXPOSURE APPARATUS, ARTICLE MANUFACTURING METHOD, AND CONTROL METHOD

(71) Applicant: CANON KABUSHIKI KAISHA, Tokyo (JP)

(72) Inventor: TOMOHIRO OKAMOTO, Ibaraki (JP)

(21) Appl. No.: 19/354,078

(22) Filed: Oct. 9, 2025

(30) Foreign Application Priority Data
Oct. 17, 2024 (JP) 2024-182171

(51) Int. Cl. G03F 7/00; G03F 9/00; G06T 7/00; G06T 7/73

(52) U.S. Cl. CPC G03F 7/70775; G03F 7/70516; G03F 7/70525; G03F 7/707; G03F 7/70716; G03F 9/7011; G03F 9/7015; G03F 9/7019; G03F 9/7092; G06T 7/001; G06T 7/0014; G06T 7/74; G06T 2207/30148; G06T 2207/30204

(57) ABSTRACT

The present disclosure provides an exposure apparatus that performs an exposure process of forming a pattern onto a substrate by using an original plate, the apparatus comprising: a chuck configured to hold the original plate; an original plate stage configured to hold the chuck; a first measurement device configured to measure a position of the original plate; a second measurement device configured to measure a position of the chuck with respect to the original plate stage; and a controller configured to control a relative position between the original plate and the substrate in the exposure process, based on a deviation of a measurement value of the second measurement device with respect to a reference value, wherein the controller is configured to execute a calibration process of calibrating the reference value based on a measurement value of the first measurement device.

### BACKGROUND

### Field of the Technology

The present disclosure relates to an exposure apparatus, an article manufacturing method, and a control method.

### Description of the Related Art

As one of the apparatuses used in a manufacturing step (lithography step) for semiconductor devices, an exposure apparatus is known which transfers the pattern of an original plate onto a substrate through a projection optical system. As such exposure apparatuses, there are generally known a stepper using a step-and-repeat scheme and a scanner using a step-and-scan scheme.

In an exposure apparatus, in order to accurately transfer the pattern of an original plate onto a substrate by controlling the relative position between the original plate and the substrate, the measurement of the position of the original plate is important. As a method of measuring the position of an original plate, there is available a method of detecting a mark on an original plate with a camera or the like. However, this method requires a considerable time to detect a mark on an original plate with a camera or the like, the frequent detection of the mark on the original plate can lead to a deterioration in productivity. In addition, since a mark on an original plate cannot be detected with a camera or the like during exposure on a substrate, it can be difficult for the method to accurately grasp the position of the original plate during the exposure. Accordingly, an exposure apparatus can be configured to measure the position of a chuck holding an original plate and control the positions of the original plate and a substrate based on the measurement value. Japanese Patent Laid-Open No. 10-154654 discloses a method of measuring the position of a reticle chuck holding an original plate (reticle) by using a plurality of interferometers.

In an exposure apparatus, for example, an original plate is sometimes thermally deformed by light irradiating an original plate during exposure on a substrate to cause the positional deviation of the original plate with respect to the chuck. In this case, only controlling the relative position between an original plate and a substrate based on the measurement value of the position of the chuck can make it difficult to accurately transfer the pattern of the original plate onto the substrate.

### SUMMARY

The present disclosure provides a technique advantageous in accurately transferring the pattern of an original plate onto a substrate.

According to one aspect of the present disclosure, there is provided an exposure apparatus that performs an exposure process of forming a pattern onto a substrate by using an original plate, the apparatus comprising: a chuck configured to hold the original plate; an original plate stage configured to hold the chuck; a first measurement device configured to measure a position of the original plate; a second measurement device configured to measure a position of the chuck with respect to the original plate stage; and a controller configured to control a relative position between the original plate and the substrate in the exposure process, based on a deviation of a measurement value of the second measurement device with respect to a reference value, wherein the controller is configured to execute a calibration process of calibrating the reference value based on a measurement value of the first measurement device, in a case where a difference between a change amount of a measurement value of the first measurement device and a change amount of a measurement value of the second measurement device from the previous calibration process exceeds a threshold.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic view showing an example of the arrangement of an exposure apparatus according to the first embodiment;

FIG. 2 is a flowchart showing an exposure process in the exposure apparatus according to the first embodiment;

FIG. 3 is a graph showing an example for explaining a calibration process;

FIG. 4 is a graph showing the transition of the measurement value of a second measurement device;

FIG. 5 is a schematic view showing an example of the arrangement of an exposure apparatus according to the second embodiment;

FIG. 6 is a schematic view showing an example of the arrangement of an exposure apparatus according to the third embodiment; and

FIG. 7 is a flowchart showing an exposure process in the exposure apparatus according to the third embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

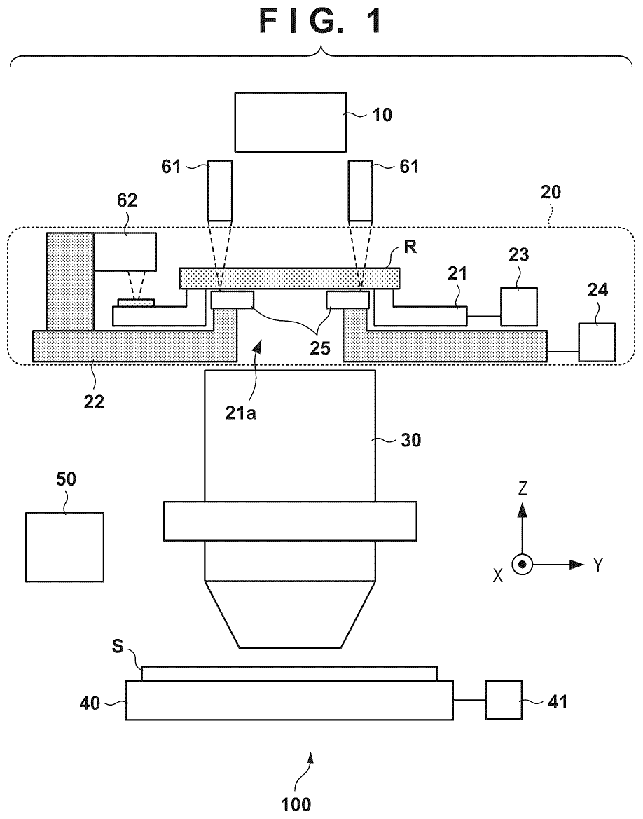

An exposure apparatus 100 according to the first embodiment of the present disclosure will be described. FIG. 1 is a schematic view showing an example of the arrangement of the exposure apparatus 100 according to the first embodiment. The exposure apparatus 100 is a lithography apparatus used in a lithography step as a manufacturing step for a device such as a semiconductor device, liquid crystal display device, and magnetic storage medium as an article. This apparatus forms a pattern on a substrate by using an original plate (reticle or mask). The exposure apparatus 100 according to the present embodiment is configured as an exposure apparatus (so-called stepper) based on a step-and-repeat scheme that transfers the pattern of an original plate R onto a substrate S while the position of the original plate R is fixed. Note, however, that the exposure apparatus 100 may be configured as an exposure apparatus (so-called scanner) based on a step-and-scan scheme that transfers the pattern of the original plate R onto the substrate S while relatively scanning the original plate R and the substrate S.

As shown in FIG. 1, the exposure apparatus 100 can include an illumination optical system 10, a stage device 20, a projection optical system 30, a substrate stage 40, a controller 50, a first measurement device 61, and a second measurement device 62. Directions will be indicated on an XYZ coordinate system in which a plane vertical to the optical axis of the projection optical system 30 is defined as an X-Y plane. Directions parallel to the X-axis, the Y-axis, and the Z-axis of the XYZ coordinate system are the X direction, the Y direction, and the Z direction, respectively. A rotating direction about the X-axis, a rotating direction about the Y-axis, and a rotating direction about the Z-axis are the θX direction, the θY direction, and the θZ direction, respectively. In addition, the position of the original plate R and the position of the substrate S include positions (postures) in the θX direction, the θY direction, and the θZ direction in addition to positions in the X direction, the Y direction, and the Z direction.

The illumination optical system 10 illuminates the original plate R with the light emitted from a light source (not shown). The stage device 20 is configured to be movable while holding the original plate R and is used for positioning the original plate R. The projection optical system 30 projects an image of the pattern of the original plate R illuminated by the illumination optical system 10 onto the substrate S at a predetermined projection magnification. The substrate stage 40 is configured to be movable while holding the substrate S and is used for positioning the substrate S. The substrate stage 40 (the substrate S) is driven by a substrate driving mechanism 41. The exposure apparatus 100 configured in this manner can transfer the pattern of the original plate R on the substrate S held by the substrate stage 40 through the projection optical system 30 by irradiating the original plate R held by the stage device 20 with exposure light from the illumination optical system 10.

The stage device 20 includes a chuck 21 that holds the original plate R (object), an original plate stage 22 that holds the chuck 21, a first driving mechanism 23, and a second driving mechanism 24. The chuck 21 is a holding member that holds a peripheral region of the original plate R and has an opening portion 21a through which exposure light having passed through the original plate R passes. The chuck 21 is configured to be movable on the original plate stage 22 and can be driven by the first driving mechanism 23 with respect to the original plate stage 22. In addition, the original plate stage 22 is configured as a base on which the chuck 21 moves and can be driven by the second driving mechanism 24. The original plate stage 22 is provided with a reference plate 25 arranged at the opening portion 21a of the chuck 21. The reference plate 25 has a reference mark detected by the first measurement device 61 (to be described later) through the original plate R. The first driving mechanism 23 and the second driving mechanism 24 constitute an original plate driving mechanism that drives the original plate R.

The controller 50 controls an exposure process of exposing the substrate S to light by using the original plate R (that is, a transfer process of transferring the pattern of the original plate R onto the substrate S) by comprehensively controlling each unit of the exposure apparatus 100. The controller 50 can be configured by, for example, a computer (information processing apparatus) including a processor such as a Central Processing Unit (CPU) and a storage unit such as a memory. The controller 50 may include a Programmable Logic Device (PLD) such as a Field Programmable Gate Array (FPGA), an Application Specific Integrated Circuit (ASIC), a general-purpose computer incorporating programs, or a combination of all or some of the above constituent elements.

The first measurement device 61 measures the position of the original plate R. The first measurement device 61 may be understood as a device that measures the positional deviation (positional shift) of the original plate R from a reference point (for example, the origin) of the coordinate system set in the exposure apparatus 100. In the present embodiment, the first measurement device 61 has an image sensor that captures an image of the reference plate 25 provided on the original plate stage 22 through the original plate R. The first measurement device 61 captures an image of a mark provided on the original plate R and an image of a reference mark provided on the original plate stage 22 (the reference plate 25) by using the image sensor and measures the position of the original plate R with respect to the original plate stage 22 based on the captured images. That is, the first measurement device 61 according to the present embodiment measures the position of the original plate R by detecting a mark provided on the original plate R and a reference mark provided on the original plate stage 22 (the reference plate 25).

The second measurement device 62 measures the position of the chuck 21 with respect to the original plate stage 22. In the present embodiment, the second measurement device 62 is attached to the original plate stage 22 and measures the position (posture) of the chuck 21 with respect to the original plate stage 22. The general driving of the original plate R requires at least three degrees of freedom in the X direction, the Y direction, and the θZ direction. The second measurement device 62 can be configured by combining a plurality of displacement sensors so as to be able to measure the positions (postures) of the chuck 21 in a plurality of directions more than the driving degrees of freedom of the original plate R. A plurality of displacement sensors used in the second measurement device 62 may be a combination of uniaxial displacement meters such as interferometers, encoders, or capacitance sensors or a combination of a plurality of types of measurement devices such as an autocollimator for the θZ direction.

In addition, as a driving scheme for the first driving mechanism 23 that drives the chuck 21 with respect to the original plate stage 22, a combination of guides and actuators can be used which can achieve driving in three degrees of freedom. As a mechanism of guiding the chuck 21 with respect to the original plate stage 22, a mechanism having a plurality of (for example, three) uniaxial rolling guides stacked on each other may be used. Alternatively, a link mechanism that controls one driving table in three-axis postures may be used.

In the exposure apparatus 100 according to the present embodiment, when the chuck 21 holds the original plate R loaded onto the chuck 21 by a transfer mechanism (not shown), the first measurement device 61 measures the position of the original plate R. More specifically, the first measurement device 61 captures an image of a mark on the original plate R and an image of a reference mark on the reference plate 25 and measures the position of the original plate R with respect to the original plate stage 22 based on the relative position between the mark on the original plate R and the reference mark on the reference plate 25 in the captured images.

The controller 50 positions the original plate R so as to establish a predetermined positional relationship between the mark on the original plate R and the reference mark on the reference plate 25 based on the measurement value of the first measurement device 61. The original plate R can be positioned by at least driving the chuck 21 using the first driving mechanism 23 or driving the original plate stage 22 using the second driving mechanism 24. The controller 50 sets, as a reference value, the position of the chuck 21 measured by the second measurement device 62 while the original plate R is positioned. The controller 50 then controls the relative position between the original plate R and the substrate S based on the deviation of the measurement value of the second measurement device 62 with respect to the reference value while measuring the position of the chuck 21 using the second measurement device 62. The relative position between the original plate R and the substrate S can be controlled by relatively driving the original plate R and the substrate S using at least one of the original plate driving mechanism (the first driving mechanism 23 and the second driving mechanism 24) and the substrate driving mechanism 41.

FIG. 1 shows an example in which the reference plate 25 is provided on the stage device 20 (the original plate stage 22). However, the reference plate 25 may be placed on a conjugate surface conjugate to a surface of the original plate R (for example, a surface of the substrate S held by the substrate stage 40 or an imaging plane of the projection optical system 30). In this case as well, the first measurement device 61 can capture an image of a mark on the original plate R and an image of a reference mark on the reference plate 25 and measure the positional deviation of the original plate R based on the captured images. Although the repeatable accuracy of the positional deviation of the original plate R measured by the first measurement device 61 can be influenced by image capturing conditions for the first measurement device 61 (that is, captured image acquisition conditions), the accuracy is on the order of about several nm. A process of checking the positional deviation of the original plate R (to be sometimes referred to as original plate positional deviation check hereinafter) based on the captured images obtained by the first measurement device 61 is executed periodically during the operation of the apparatus. If, for example, the reference plate 25 is provided on the original plate stage 22, the original plate positional deviation check is executed concurrently with another sequence in a period in which no exposure process is performed, such as a period in which the substrate S is replaced on the substrate stage 40, thereby reducing the influence on productivity. The position information of the original plate R obtained by the original plate positional deviation check can be used for control on an exposure process by the controller 50 so as to improve the exposure result on the substrate S.

Assume that the production of a new lot is started upon loading of the original plate R onto the stage device 20 of the exposure apparatus 100. In this case, the original plate R or the chuck 21 has a large temperature change immediately after the start of the production (immediately after the startup of the apparatus), and hence a large positional deviation can occur on the original plate R. Subsequently, as the exposure process (operation) continuously proceeds under the same exposure conditions, the temperature change is stabilized to reduce the positional deviation of the original plate R. In general, the original plate positional deviation check using the first measurement device 61 is executed between exposure processes, such as a period in which the substrate S is replaced, and cannot be executed during an exposure process. In order to accurately control the position of the original plate R even immediately after the start of lot production at which the positional deviation of the original plate R increases due to a temperature change, there is a need to accurately grasp the positional deviation of the original plate R even during an exposure process. Accordingly, the exposure apparatus 100 according to the present embodiment is provided with the second measurement device 62 that measures the position of the chuck 21 with respect to the original plate stage 22.

The second measurement device 62 can measure the position of the chuck 21 in real time even during an exposure process. Since the original plate R is held by the chuck 21, the position of the chuck 21 measured by the second measurement device 62 can be converted into the position of the original plate R. That is, even during an exposure process, the position of the original plate R can be accurately controlled in real time based on the deviation of the measurement value of the second measurement device 62 with respect to a reference value. However, as an exposure process is repeatedly performed, the original plate R sometimes undergoes positional deviation with respect to the chuck 21. Since the second measurement device 62 cannot measure such positional deviation of the original plate R with respect to the chuck 21, the occurrence of the positional deviation can make it difficult to accurately control the position of the original plate R. That is, it can be difficult to accurately transfer the pattern of the original plate R onto the substrate S. Accordingly, the exposure apparatus 100 according to the present embodiment performs a calibration process of calibrating the reference value used to calculate the deviation of the measurement value of the second measurement device 62 based on the result of original plate positional deviation check (that is, the measurement value of the first measurement device 61). A calibration process may be understood as a process of resetting the reference value of the second measurement device 62 with reference to the result of the original plate positional deviation check.

In addition, every time original plate positional deviation check is performed using the first measurement device 61, a calibration process may be executed. In general, however, the first measurement device 61 configured by using the image sensor is lower in measurement accuracy than the second measurement device 62 configured by using an interferometer or the like. For this reason, if a calibration process is executed every time original plate positional deviation check is performed using the first measurement device 61, a measurement error that has occurred in the first measurement device 61 can be reflected in the measurement value of the second measurement device 62. That is, variation due to the measurement repeatability of the first measurement device 61 can be reflected in the measurement value of the second measurement device 62. The exposure apparatus 100 according to the present embodiment executes a calibration process if the difference between the change amount of the measurement value of the first measurement device 61 and the change amount of the measurement value of the second measurement device 62 from that in the previous calibration process exceeds a threshold.

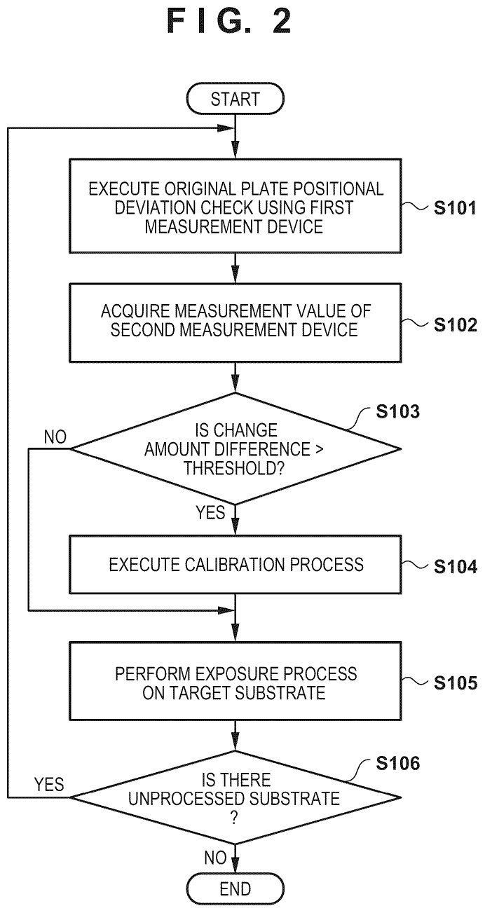

FIG. 2 is a flowchart showing an exposure process in the exposure apparatus 100 according to the present embodiment. The flowchart in FIG. 2 can be started when an exposure process is performed with respect to the substrate S of a new lot. An exposure process with respect to the substrate S of a new lot sometimes uses the original plate R loaded to the chuck 21 and other times use the original plate R that has already been held by the chuck 21. In either case, before the start of an exposure process with respect to the leading substrate S of each lot, original plate positional deviation check using the first measurement device 61 is executed. Subsequently, if the difference between the change amount of the measurement value of the first measurement device 61 and the change amount of the measurement value of the second measurement device 62 from that in the previous calibration process exceeds a threshold, a calibration process is executed.

In step S101, the controller 50 executes original plate positional deviation check using the first measurement device 61. Original plate positional deviation check can be executed while, for example, the substrate S on the substrate stage 40 is replaced before the start of an exposure process with respect to each substrate S in a lot. In step S102, the controller 50 acquires the measurement value of the second measurement device 62. In the present embodiment, step S102 is performed after step S101. However, step S102 may be performed before step S101 or steps S101 and S102 may be concurrently performed.

In step S103, the controller 50 determines whether the difference between the change amount of the measurement value of the first measurement device 61 and the change amount of the measurement value of the second measurement device 62 from that in the previous calibration process has exceeded a threshold. If the change amount difference exceeds the threshold, the controller 50 has executed a calibration process in step S104. In contrast to this, if the change amount difference has not exceeded the threshold, the controller 50 keeps using the reference value without executing a calibration process in step S104.

In this case, the second measurement device 62 measures the positions of the chuck 21 in a plurality of directions including at least the X direction, the Y direction, and the θZ direction. Accordingly, the controller 50 may set a threshold for each of the plurality of directions in which the positions of the chuck 21 are measured by the second measurement device 62 and determine whether each change amount difference has exceeded a corresponding threshold. In this case, the controller 50 may execute a calibration process if the change amount difference in any one of the plurality of directions has exceeded the threshold.

In step S105, the controller 50 performs an exposure process with respect to the target substrate S in the lot. As described above, the controller 50 controls the relative position between the original plate R and the substrate S during the exposure process based on the deviation of the measurement value of the second measurement device 62 with respect to the reference value. In step S106, the controller 50 determines whether there is any substrate S not having undergone an exposure process (to be sometimes referred to as the unprocessed substrate S hereinafter) in the lot. If there is any unprocessed substrate S, the process advances to step S101; otherwise, the controller 50 terminates the flowchart.

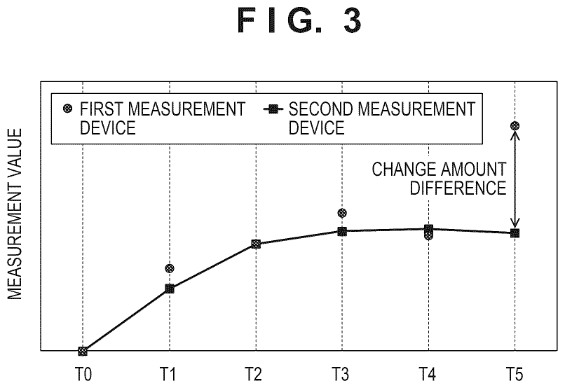

FIG. 3 is a graph showing an example for explaining a calibration process. The abscissa in FIG. 3 represents timings T1 to T5 when original plate positional deviation check is executed by using the first measurement device 61. The ordinate in FIG. 3 represents each of the measurement values obtained by the first measurement device 61 and the second measurement device 62. In the example shown in FIG. 3, a calibration process is performed at a timing T0, and the reference value of a second measurement value 27 is set to 0. Thereafter, the controller 50 determines whether the change amount difference has exceeded the threshold at each of the timings T1 to T5 at which original plate positional deviation check has been executed and executes a calibration process at the timing T5 at which the change amount difference has exceeded the threshold. For example, a calibration process can include a process of correcting (offsetting) the reference value of the second measurement device 62 based on the change amount difference at the timing T5. Alternatively, a calibration process can include a process of positioning the original plate R based on the measurement value of the first measurement device 61 at the timing T5 and setting the measurement value of the second measurement device 62 in this state as a reference value.

As described above, the exposure apparatus 100 according to the present embodiment can accurately control the relative position between the original plate R and the substrate S based on the measurement value of the second measurement device 62 during an exposure process because a calibration process is performed if the change amount difference exceeds the threshold. In addition, the exposure apparatus 100 can reduce the degree of the reflection of the measurement error caused in the first measurement device 61 in the measurement value of the second measurement device 62 because the reference value of the second measurement device 62 is continuously used if the change amount difference does not exceed the threshold.

In this case, to prevent a deterioration in the productivity of the exposure apparatus 100, original plate positional deviation check is preferably executed in a period in which the substrate S on the substrate stage 40 is replaced. However, limitation is not made thereto. For example, original plate positional deviation check may be executed in a period other than a period in which the substrate S is replaced, for example, after the lapse of a predetermined period of time since the previous original plate positional deviation check, from the viewpoint of guaranteeing exposure accuracy. Note, however, that if another sequence cannot be executed concurrently with original plate positional deviation check, the productivity of the exposure apparatus 100 can deteriorate according to the time required for the original plate positional deviation check.

Factors that consume time include irregular occasions such as waiting for a task outside the apparatus and check on automatically set parameters such as warning and retry. However, a predetermined period of time sometimes repeatedly elapses as long as the processing of the substrates S is continued within the same lot, such as multipoint measurement before an exposure process. For this reason, when an exposure process is to be performed for each of the plurality of substrates S in the same lot, it is possible to omit original plate positional deviation check that has not been executed concurrently with another sequence (for example, the replacement of the substrate S on the substrate stage 40) from the history of the previous lot. A deterioration in productivity can be reduced without any influence on an exposure result by omitting original plate positional deviation check on the next lot upon checking from the history of the previous lot whether original plate positional deviation check has not been executed concurrently with another sequence and a change amount difference has not exceeded the threshold.

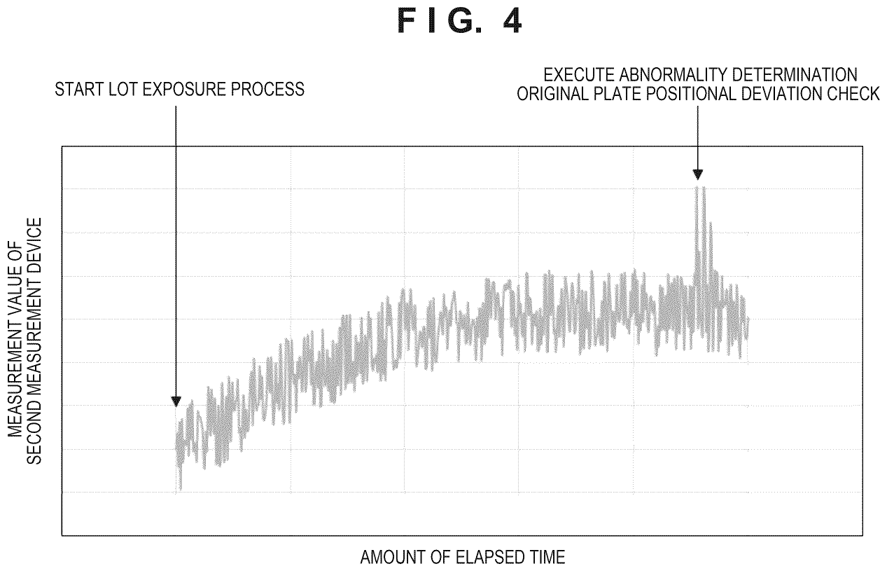

The exposure apparatus 100 according to the present embodiment can determine the execution timing of original plate positional deviation check using the first measurement device 61 (that is, the measurement timing of the position of the original plate R using the first measurement device 61) based on the measurement value of the second measurement device 62. FIG. 4 is a graph showing the transition of the measurement value of the second measurement device 62 in a period in which an exposure process is performed with respect to the plurality of substrates S in the lot. The measurement value of the second measurement device 62 has a predetermined amplitude in accordance with a vibration state in the exposure apparatus 100. It is obvious that after the start of an exposure process with respect to the plurality of substrates S in the lot, drift has occurred due to the heat generated by exposure light, and the measurement values are stabilized after the lapse of a predetermined period of time. When the measurement value of the second measurement device 62 is reflected in the control of the position of the original plate R, the moving average of the measurement values obtained by the second measurement device 62 is calculated, and the influence of vibration can be reduced by using the resultant value. In addition, it is possible to obtain useful information for abnormality determination from the measurement value of the second measurement device 62. For example, as shown in FIG. 4, if the amplitude of the measurement value of the second measurement device 62 temporarily increases as compared with the preceding amplitude, it can be considered that external force that has not existed is applied to the chuck 21 due to some factor. Accordingly, the controller 50 determines the occurrence of an abnormality if the amplitude of the measurement value of the second measurement device 62 falls outside an allowable range and executes original plate positional deviation check using the first measurement device 61. If a change amount difference exceeds a threshold, a calibration process is executed. This makes it possible to continue an exposure process upon calibrating (correcting) the reference value of the second measurement device 62 even if the original plate R has deviated from the chuck 21 due to unexpected external force.

As another method of determining the execution timing of original plate positional deviation check based on the measurement value of the second measurement device 62, there is available a method of determining to execute original plate positional deviation check if the change amount of the measurement value of the second measurement device 62 exceeds a specified amount after the reference value is calibrated by a calibration process. Causes of a change in the measurement value of the second measurement device 62 include a case where the chuck 21 has moved with respect to the original plate stage 22 and a case where drift has occurred in the measurement value of the second measurement device 62. A period in which the measurement value of the second measurement device 62 has changed indicates the possibility that the stage device 20 has changed instead of being in a thermal equilibrium state, and hence a stable exposure process can be executed by executing original plate positional deviation check. On the other hand, if an exposure process is continuously performed with respect to a plurality of substrates in the same lot, and the measurement value of the second measurement device 62 is stable, the effect obtained by executing original plate positional deviation check is low. In such a case, original plate positional deviation check can be omitted.

In the present embodiment described above, a calibration process is executed if the difference (change amount difference) between the change amount of the measurement value of the first measurement device 61 and the change amount of the measurement value of the second measurement device 62 from that in the previous calibration process exceeds the threshold. This threshold is preferably set based on the measurement repeatability accuracy of original plate positional deviation check. The measurement repeatability accuracy may be understood as a measurement error caused in the first measurement device 61. For example, the threshold can be set to the maximum value of the measurement error estimated to occur in the first measurement device 61 by an experiment or simulation. In addition, the measurement repeatability accuracy can change depending on conditions (for example, image capturing conditions) in executing original plate positional deviation check. Accordingly, conditions for original plate positional deviation check in a calibration process are preferably set to be advantageous conditions (that is, accurate conditions) as compared with conditions for original plate positional deviation check in a process other than a calibration process. For example, the measurement time of the first measurement device 61 (the image capturing time of the image sensor) is prolonged, and/or the average value of measurement values obtained by a plurality of times of measurement by the first measurement device 61 is used. This makes it possible to improve the measurement repeatability accuracy of original plate positional deviation check (that is, to reduce a measurement error in the first measurement device 61).

### Second Embodiment

An exposure apparatus 100 according to the second embodiment of the present disclosure will be described. The present embodiment basically inherits the first embodiment and can comply with the first embodiment except for the matters described below.

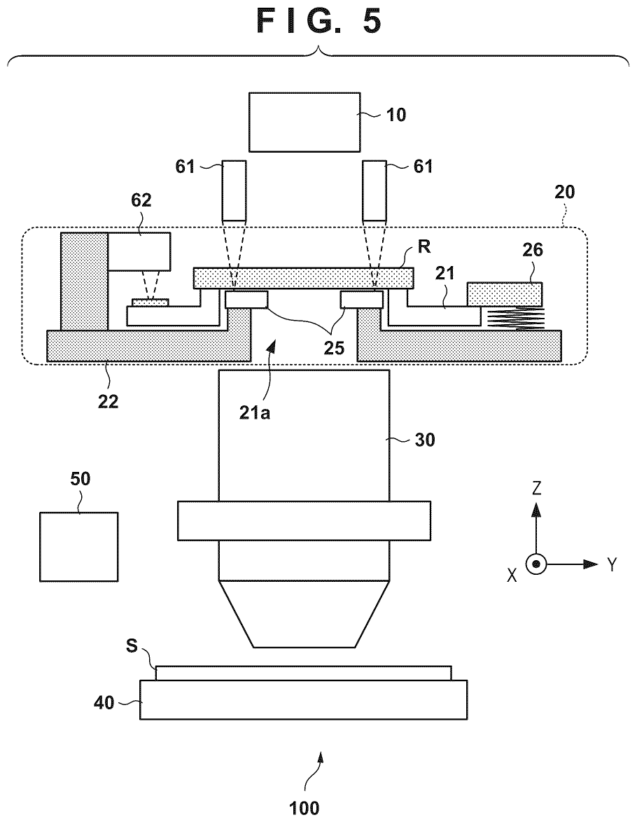

FIG. 5 is a schematic view showing an example of the arrangement of the exposure apparatus 100 according to the second embodiment. Referring to FIG. 5, illustrations of an original plate driving mechanism (a first driving mechanism 23 and a second driving mechanism 24) and a substrate driving mechanism 41 will be omitted. In the exposure apparatus 100 according to the present embodiment, a stage device 20 is additionally provided with a fixing mechanism 26 that fixes a chuck 21 on an original plate stage 22. The fixing mechanism 26 can include a force generating unit that generates a force for pressing the chuck 21 against the original plate stage 22. As the force generating unit of the fixing mechanism 26, for example, an arbitrary one of a spring, an air pressure, a magnetic force, and the like can be used. The fixing mechanism 26 can be arranged at a plurality of portions of the chuck 21. That is, a plurality of fixing mechanisms 26 may be provided on the chuck 21. This can reduce the deformation of the chuck 21 fixed to the original plate stage 22 with the fixing mechanisms 26.

The fixing mechanism 26 described above can be applied to a step-and-repeat exposure apparatus (stepper) that exposes each shot region of a substrate S to light while the position of an original plate R is fixed. When the original plate R is to be loaded into the stage device 20 (that is, on the chuck 21), the fixing mechanism 26 cancels the fixing of the chuck 21 on the original plate stage 22 and fixes the chuck 21 to the original plate stage 22 upon alignment between the original plate R and the substrate S. Fixing the chuck 21 to the original plate stage 22 with the fixing mechanism 26 can improve the rigidity of the chuck 21 and the positional stability of the chuck 21 with respect to the original plate stage 22. Although using the fixing mechanism 26 will improve the positional stability of the chuck 21 with respect to the original plate stage 22, it is difficult to completely prevent the occurrence of a positional deviation on the nanometer order. For this reason, even in the stage device 20 having the fixing mechanism 26, original plate positional deviation check is periodically executed by using the first measurement device 61.

An example of executing the flowchart of FIG. 2 in the exposure apparatus 100 including the fixing mechanism 26 will be described next. The exposure apparatus 100 according to the present embodiment can also basically operate in accordance with the flowchart of FIG. 2. Note, however, that the relative position between the original plate R and the substrate S in an exposure process can be controlled by driving the substrate stage 40. A calibration process is executed if a change amount difference exceeds a threshold as in the first embodiment.

### Third Embodiment

An exposure apparatus 100 according to the third embodiment of the present disclosure will be described. The present embodiment basically inherits the first embodiment and can comply with the first embodiment except for the matters described below. In addition, the second embodiment may be applied to the present embodiment.

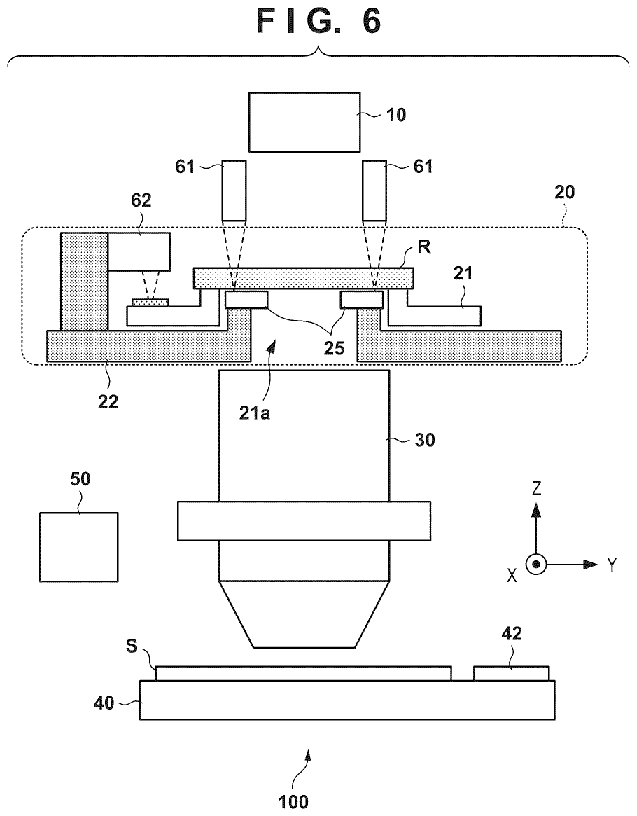

FIG. 6 is a schematic view showing an example of the arrangement of the exposure apparatus 100 according to the third embodiment. Referring to FIG. 6, illustrations of an original plate driving mechanism (a first driving mechanism 23 and a second driving mechanism 24) and a substrate driving mechanism 41 will be omitted. Unlike the first embodiment, the exposure apparatus 100 according to the present embodiment has a second reference plate 42 provided on a substrate stage 40. The second reference plate 42 has a second reference mark detected by a first measurement device 61 through an original plate R and a projection optical system 30. Note that in the present embodiment, a reference plate 25 provided on the original plate stage 22 will be sometimes referred to as the “first reference plate 25” and a reference mark provided on the reference plate 25 will be sometimes referred to as the “first reference mark”.

The first measurement device 61 can be configured to detect a mark on the original plate R and a mark on the substrate S for the alignment between the original plate R and the substrate S. More specifically, the first measurement device 61 is configured to capture an image of the mark on the original plate R and an image of the mark on the substrate S with an image sensor included in the first measurement device 61. Accordingly, the first measurement device 61 can capture (detect) an image of the second reference mark on the second reference plate 42 provided on the substrate stage 40 and an image of the mark on the original plate R and measure the position of the original plate R based on the captured images. Accordingly, the exposure apparatus 100 according to the present embodiment is configured to be able to execute original plate positional deviation check using the first reference plate 25 (first reference mark) on the original plate stage 22 and original plate positional deviation check using the second reference plate 42 (second reference mark) on the substrate stage 40. In the following description, original plate positional deviation check using the first reference plate 25 on the original plate stage 22 will be sometimes referred to as “first original plate positional deviation check (first measurement process)”. In addition, original plate positional deviation check using the second reference plate 42 on the substrate stage 40 will be sometimes referred to as “second original plate positional deviation check (second measurement process)”.

In this case, the first original plate positional deviation check and the second original plate positional deviation check differ whether the projection optical system 30 and the substrate stage 40 (the second reference plate 42) are used or not. In the first original plate positional deviation check, since the projection optical system 30 is not used, any measurement error due to the axial shift (for example, aberration) of the projection optical system 30 is not included in the measurement value of the first measurement device 61. In contrast to this, in the second original plate positional deviation check, since the projection optical system 30 is not used, a measurement error due to the axial shift of the projection optical system 30 is included in the measurement value of the first measurement device 61. Therefore, the second original plate positional deviation check can accurately obtain the position of the original plate R in consideration of a projection deviation on the substrate S due to the projection optical system 30 as compared with the first original plate positional deviation check.

In addition, in the first original plate positional deviation check, since the substrate stage 40 (the second reference plate 42) is not used, the first measurement device 61 can measure the position of the original plate R concurrently with the execution of another sequence such as the replacement of the substrate S on the substrate stage 40. In contrast to this, in the second original plate positional deviation check, since the substrate stage 40 (the second reference plate 42) is used, it is difficult to measure the position of the original plate R by using the first measurement device 61 concurrently with the execution of another sequence such as the replacement of the substrate S on the substrate stage 40. That is, executing the second original plate positional deviation check for every replacement of the substrate S on the substrate stage 40 can lead to a deterioration in the productivity of the exposure apparatus 100 according to the time required for the checks. Therefore, the first original plate positional deviation check is advantageous over the second original plate positional deviation check from the viewpoint of the productivity of the exposure apparatus 100.

Accordingly, the present embodiment is configured to determine whether the change amount difference obtained from the result of the first original plate positional deviation check has exceeded a threshold and perform a calibration process using the result of the second original plate positional deviation check that can measure the position of the original plate R more accurately than the first original plate positional deviation check. In a calibration process according to the present embodiment, the reference value of a second measurement device 62 is corrected (offset) by the change amount difference obtained from the second original plate positional deviation check. Alternatively, in a calibration process, the original plate R is positioned based on the result of the second original plate positional deviation check, and the measurement value of the second measurement device 62 in this state is set to a reference value.

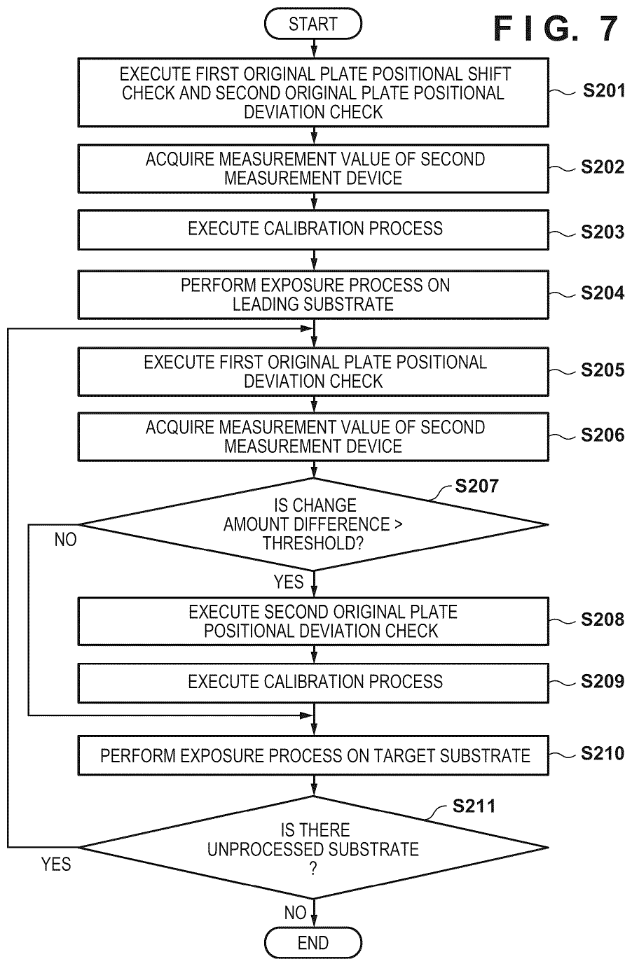

FIG. 7 is a flowchart showing an exposure process in the exposure apparatus 100 according to the present embodiment. The flowchart of FIG. 7 shows an example of an exposure process performed with respect to the substrate S of a new lot.

In step S201, a controller 50 executes both the first original plate positional deviation check and the second original plate positional deviation check using the first measurement device 61 before an exposure process with respect to the leading substrate S in the lot. In step S202, the controller 50 acquires the measurement value of the second measurement device 62.

In step S203, the controller 50 executes a calibration process by using the result of the second original plate positional deviation check. In step S204, the controller 50 performs an exposure process with respect to the leading substrate S in the lot. During the exposure process with respect to the leading substrate S, the controller 50 controls the relative position between the original plate R and the substrate S based on the deviation of the measurement value of the second measurement device 62 with respect to the reference value calibrated by the calibration process in step S203.

Steps S205 to S211 are steps performed with respect to the second and subsequent the substrates S in the lot. In step S205, the controller 50 executes the first original plate positional deviation check using the first measurement device 61. The first original plate positional deviation check can be executed while the substrate S on the substrate stage 40 is replaced. In step S206, the controller 50 acquires the measurement value of the second measurement device 62. In the present embodiment, step S206 is performed after step S205. However, step S206 may be performed before step S205, or steps S205 and S206 may be concurrently performed.

In step S207, the controller 50 determines whether the difference (change amount difference) between the change amount of the measurement value of the first measurement device 61 (the result of the first original plate positional deviation check) and the change amount of the measurement value of the second measurement device 62 from that in the previous calibration process has exceeded a threshold. That is, the controller 50 determines whether the change amount difference has exceeded the threshold by using the result of the first original plate positional deviation check. If the change amount difference has exceeded the threshold, the process advances to step S208. In this case, the controller 50 executes the second original plate positional deviation check using the first measurement device 61 in step S208 and executes a calibration process by using the result of the second original plate positional deviation check in step S209. If the change amount difference has not exceeded the threshold, the process advances to step S210 without executing the calibration process in steps S208 and S209.

In step S210, the controller 50 performs an exposure process with respect to the target substrate S in the lot. As described above, the controller 50 controls the relative position between the original plate R and the substrate S based on the deviation of the measurement value of the second measurement device 62 with respect to the reference value during an exposure process. In step S211, the controller 50 determines whether there is any substrate S not having undergone an exposure process (to be sometimes referred to as the unprocessed substrate S hereinafter) in the lot. If there is the unprocessed substrate S, the process advances to step S204; otherwise, the controller 50 terminates the flowchart.

As described above, the present embodiment is configured to determine whether the change amount difference obtained from the result of the first original plate positional deviation check has exceeded a threshold and perform a calibration process by using the result of the second original plate positional deviation check. This makes it possible to more accurately control the position of the original plate R based on the measurement value of the second measurement device 62 during an exposure process and reduce a deterioration in the productivity of the exposure apparatus 100.

In this case, the first measurement device 61 according to the present embodiment is not limited to the arrangement configured to capture an image of the second reference mark on the second reference plate 42 and an image of the mark on the original plate R by using the image sensor. For example, the first measurement device 61 may be provided on the substrate stage 40 to detect light (transmitted light) passing through the mark on the original plate R and the second reference mark on the second reference plate 42. In this arrangement, the mark on the original plate R and the second reference mark each can be configured as a slit pattern. The first measurement device 61 can detect the intensity of transmitted light while the original plate R moves and measure the position of the original plate R based on the positional relationship between the original plate R and the substrate stage 40 (the second reference plate 42) at the time when the transmitted light has the highest intensity. That is, the second original plate positional deviation check can be executed by using transmitted light. As described above, the second original plate positional deviation check using transmitted light can detect the positional deviation of the original plate R more accurately than the second original plate positional deviation check using captured images.

### Embodiment of Article Manufacturing Method

An article manufacturing method according to an embodiment of the present disclosure is suitable for manufacturing an article, for example, a microdevice such as a semiconductor device or an element having a fine structure. The article manufacturing method according to the present embodiment includes a transfer step of transferring the pattern of an original plate onto a substrate by using the above exposure apparatus, a processing step of processing the substrate on which the pattern is transferred in the transfer step, and a manufacturing step of manufacturing an article from the substrate processed in the processing step. The transfer step may be understood as an exposure step of exposing the substrate coated with a photosensitive agent to light. The processing step may be understood as a developing step of developing the substrate (photosensitive agent) having undergone the exposure step. In addition, the article manufacturing method includes other known steps (oxidation, deposition, vapor deposition, doping, planarization, etching, resist removal, dicing, bonding, packaging, and the like). The article manufacturing method according to the present embodiment is advantageous in at least one of the performance, quality, productivity, and production cost of the article, as compared to conventional methods.

### Other Embodiments

Embodiments of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-182171, filed on Oct. 17, 2024, which is hereby incorporated by reference herein in its entirety.

What is claimed is:

1. An exposure apparatus that performs an exposure process of forming a pattern onto a substrate by using an original plate, the apparatus comprising:
a chuck configured to hold the original plate;
an original plate stage configured to hold the chuck;
a first measurement device configured to measure a position of the original plate;
a second measurement device configured to measure a position of the chuck with respect to the original plate stage; and
a controller configured to control a relative position between the original plate and the substrate in the exposure process, based on a deviation of a measurement value of the second measurement device with respect to a reference value,
wherein the controller is configured to execute a calibration process of calibrating the reference value based on a measurement value of the first measurement device, in a case where a difference between a change amount of a measurement value of the first measurement device and a change amount of a measurement value of the second measurement device from the previous calibration process exceeds a threshold.

2. The apparatus according to claim 1, wherein the controller is configured to continuously use the reference value without executing the calibration process, in a case where the difference does not exceed the threshold.

3. The apparatus according to claim 1, wherein the calibration process includes a process of correcting the reference value by the difference.

4. The apparatus according to claim 1, wherein the calibration process includes a process of positioning the original plate based on a measurement value of the first measurement device and setting a measurement value of the second measurement device in a state where the original plate is positioned, as the reference value.

5. The apparatus according to claim 1, wherein the controller is configured to determine a measurement timing of a position of the original plate by the first measurement device, based on a measurement value of the second measurement device.

6. The apparatus according to claim 1, wherein the first measurement device is configured to measure a position of the original plate by detecting a relative position between a mark provided on the original plate and a mark provided on the original plate stage.

7. The apparatus according to claim 1, further comprising a substrate stage configured to hold the substrate,
wherein the first measurement device measures a position of the original plate by detecting a relative position between a mark provided on the original plate and a mark provided on the substrate stage.

8. The apparatus according to claim 1, further comprising a substrate stage configured to hold the substrate,
wherein the first measurement device is configured to perform a first measurement process of measuring a position of the original plate by detecting a relative position between a mark provided on the original plate and a mark provided on the original plate stage, and a second measurement process of measuring a position of the original plate by detecting a mark provided on the original plate and a mark provided on the substrate stage, and
the controller is configured to perform the second measurement process in a case where the difference obtained from the first measurement process exceeds the threshold and execute the calibration process by using a measurement value of the first measurement device in the second measurement process.

9. The apparatus according to claim 1, further comprising a fixing mechanism configured to fix the chuck to the original plate stage,
wherein the controller is configured to control the fixing mechanism to cancel fixing of the chuck to the original plate stage when an original plate is loaded to the chuck, and fix the chuck to the original plate stage after performing alignment between the original plate and the substrate.

10. The apparatus according to claim 1, further comprising a substrate stage configured to hold the substrate,
wherein the exposure process is performed with respect to each of a plurality of substrates, and
wherein the controller is configured to cause the first measurement device to measure a position of the original plate in a period in which a substrate on the substrate stage is replaced.

11. The apparatus according to claim 1, wherein a measurement accuracy of the first measurement device is lower than a measurement accuracy of the second measurement device.

12. An article manufacturing method comprising:
forming a pattern onto a substrate by using an exposure apparatus defined in claim 1;
processing the substrate onto which the pattern has been transferred; and
manufacturing an article from the processed substrate.

13. A control method for an exposure apparatus that includes a chuck configured to hold an original plate and an original plate stage configured to holding the chuck, and transfers a pattern of the original plate onto a substrate, the method comprising:
measuring a position of the original plate;
measuring a position of the chuck with respect to the original plate stage;
controlling a relative position between the original plate and the substrate, based on a deviation of a measurement value obtained in the measuring the position of the chuck with respect to a reference value; and
executing a calibration process of calibrating the reference value based on a measurement value obtained in the measuring the position of the original plate,
wherein the calibration process is executed in a case where a difference between a change amount of a measurement value obtained in the measuring the position of the original plate and a change amount of a measurement value obtained in the measuring the position of the chuck from the previous calibration process exceeds a threshold.
